(19) United States
(12) Patent Application Publication
(10) Pub. No.: US 2026/0206601 A1
(43) Pub. Date: Jul. 16, 2026

(54) SEMICONDUCTOR DEVICE

(71) Applicant: Samsung Electronics Co., Ltd., Suwon-si (KR)

(72) Inventors: Jungwon CHOE, Suwon-si (KR); Sunghoon KIM, Suwon-si (KR); Jungseok HWANG, Suwon-si (KR)

(73) Assignee: Samsung Electronics Co., Ltd., Suwon-si (KR)

(21) Appl. No.: 19/311,324

(22) Filed: Aug. 27, 2025

(30) Foreign Application Priority Data
Jan. 10, 2025 (KR) 10-2025-0003905

(51) Int. Cl. H01L 23/60; H01L 23/528; H10D 84/85

(52) U.S. Cl. CPC H10W 42/60; H10D 84/85; H10W 20/427

(57) ABSTRACT

A semiconductor device includes a first gate structure extending in a first direction, a second gate structure extending in the first direction and spaced apart from the first gate structure in a second direction, a first active region intersecting the first gate structure in the second direction, a second active region intersecting the second gate structure in the second direction, a dummy active region contacting a lower surface of the first gate structure and a lower surface of the second gate structure, extending in the second direction, and separated from the first active region and the second active region, wherein the first gate structure and the second gate structure are electrically separated from each other.

### CROSS-REFERENCE TO RELATED APPLICATION(S)

This application claims the benefit under 35 USC 119(a) of Korean Patent Application No. 10-2025-0003905 filed on Jan. 10, 2025 in the Korean Intellectual Property Office, the entire disclosure of which is incorporated herein by reference for all purposes.

### BACKGROUND

Some example embodiments relate to a semiconductor device.

Semiconductor devices may be classified into semiconductor memory devices that store logical data, semiconductor logic devices that process logical data, hybrid semiconductor devices that include memory elements and logic elements, and the like. In general, semiconductor devices may be manufactured to include transistors and may also include antenna devices in a fixed area of a semiconductor substrate. The antenna device naturally releases plasma ions into the semiconductor substrate during the manufacturing process of the semiconductor device, thereby helping to protect the transistor from plasma damage.

However, as the width of the transistor changes to improve the operating speed of the semiconductor device, additional area is to be used to accommodate the antenna device. This causes problems such as an increase in the size of the semiconductor device and a decrease in the degree of freedom of the metal line.

### SUMMARY

Some example embodiments may provide a semiconductor device having a structure in which plasma ions are emitted into an interior of a semiconductor substrate, while reducing a circuit area and improving a degree of freedom of metal lines.

According to some example embodiments, a semiconductor device includes a first gate structure including a first line portion extending in a first direction, parallel to an upper surface of a substrate, and a first extension portion contacting an end of the first line portion; a second gate structure including a second line portion extending in the first direction and spaced apart from the first line portion in a second direction, and a second extension portion contacting an end of the second line portion and spaced apart from the first extension portion in the second direction, the second direction being parallel to the upper surface of the substrate and intersecting the first direction; a first active region intersecting the first line portion in the second direction; a second active region intersecting the second line portion in the second direction; a dummy active region contacting a lower surface of the first extension portion and a lower surface of the second extension portion, extending in the second direction, and separated from the first active region and the second active region; and a plurality of metal lines including a first metal line electrically connected to the first extension portion and a second metal line electrically connected to the second extension portion and electrically isolated from the first metal line.

Alternatively or additionally according to some example embodiments, a semiconductor device includes a plurality of gate structures respectively extending in a first direction, parallel to an upper surface of a substrate, and arranged in a second direction parallel to the upper surface of the substrate and intersecting the first direction, at least some of the plurality of gate structures electrically isolated from each other; a plurality of active regions respectively intersecting at least one of the plurality of gate structures in the second direction, and arranged in the second direction; and a dummy active region separated from the plurality of active regions and extending in the second direction to contact respective lower surfaces of the plurality of gate structures.

Alternatively or additionally according to some example embodiments, a semiconductor device includes a plurality of first gate structures respectively including a first line portion extending in a first direction, parallel to an upper surface of a substrate, and a first extension portion contacting an end of the first line portion, and arranged in a second direction intersecting the first direction; a plurality of first active regions respectively intersecting at least one of the plurality of first gate structures and arranged in the second direction; a plurality of second gate structures respectively including a second line portion extending in the first direction and a second extension portion contacting an end of the second line portion, arranged in the second direction, and spaced apart from the plurality of first gate structures in the first direction; a plurality of second active regions respectively intersecting at least one of the plurality of second gate structures, and arranged in the second direction; and a dummy active region extending in the first direction and the second direction to contact lower surfaces of the respective first extension portions of the plurality of first gate structures and lower surfaces of the respective second extension portions of the plurality of second gate structures. At least some of the respective first extension portions of the plurality of first gate structures and the respective second extension portions of the plurality of second gate structures are electrically isolated from each other.

Alternatively or additionally according to some example embodiments, there is provided a method of fabricating a semiconductor device comprising provisioning a substrate, forming a dummy active region on the substrate, forming a first metal line and a second metal line at least partially overlapping the dummy active region, and processing the substrate with a plasma process. The processing the substrate with a plasma process includes discharging ions through the dummy active region.

In some example embodiments, the discharging the ions includes discharging the ions to ground.

In some example embodiments, the processing the substrate with a plasma process includes grounding the substrate.

In some example embodiments, the plasma process includes at least one of an etching process and a deposition process.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a layout diagram of a semiconductor device according to a comparative example different from some example embodiments;

FIG. 2 is a layout diagram of a semiconductor device according to some example embodiments;

FIG. 3 is a cross-sectional view taken along line I-I′ of FIG. 2;

FIG. 4 is a cross-sectional view taken along line II-II′ of FIG. 2;

FIG. 5 is a cross-sectional view taken along line III-III′ of FIG. 2;

FIGS. 6 to 9 are layout diagrams of semiconductor devices according to some example embodiments;

FIGS. 10 to 11 are layout diagrams of semiconductor devices according to some example embodiments;

FIG. 12 is a layout diagram of a semiconductor device according to some example embodiments;

FIGS. 13 to 15 are layout diagrams of semiconductor devices according to some example embodiments; and

FIG. 16 is a layout diagram of a semiconductor device according to some example embodiments.

### DETAILED DESCRIPTION

Hereinafter, some example embodiments will be described with reference to the accompanying drawings.

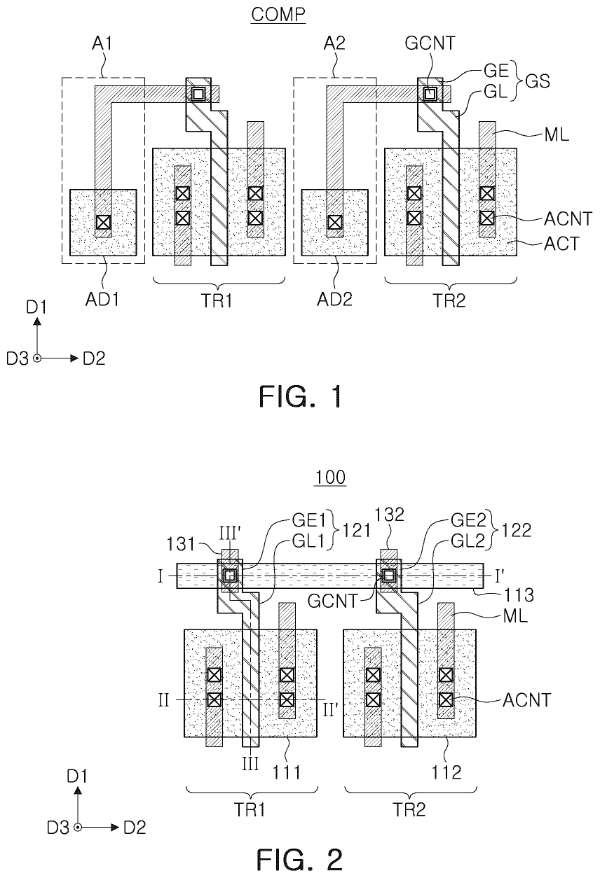

FIG. 1 is a layout diagram of a semiconductor device according to a comparative example different from example embodiments.

In general, a semiconductor device may include a transistor, a metal line, other elements, and and/or the like disposed on and/or in a semiconductor substrate in a first direction D1 parallel to the upper surface of the substrate and a second direction D2 parallel to the upper surface of the substrate and intersecting the first direction D1. For example, a transistor may include a gate, a source, and a drain. The gate, the source, and the drain may be connected to one or more of a power source, a transistor, other elements, and the like through the metal lines, thereby forming a semiconductor circuit.

In a semiconductor manufacturing process for forming a semiconductor device, plasma ions may be irradiated, for example, to the metal lines. The metal lines may serve as an antenna and may collect electronic dust. Plasma damage may occur in which the gate insulating layer is damaged due to plasma ions collected through the metal lines. An antenna ratio is used as an index that quantitatively indicates the degree of plasma damage. The antenna ratio may be defined as the ratio of the surface area of a conductor exposed to plasma to the surface area of the gate insulating layer. The larger the antenna ratio, the more serious the plasma damage may be.

Meanwhile, as the performance of the semiconductor device is improved, the size of the elements included in the semiconductor device tends to decrease. For example, to shorten the channel length of the transistor, the width of the gate structure constituting the transistor may decrease. Due to the decrease in the width of the gate structure, a separate area for disposing the antenna device may be required in the semiconductor device.

Referring to FIG. 1, a semiconductor device COMP according to a comparative example different from those of example embodiments is illustrated. The semiconductor device COMP may include a first transistor TR1, a second transistor TR2, a first antenna device AD1, and a second antenna device AD2.

Each of the first and second transistors TR1 and TR2 may include a gate structure GS extending in a first direction D1 and an active region ACT intersecting the gate structure GS in a second direction D2. The gate structure GS may provide a gate, and the active region ACT may provide a source and a drain that are adjacent in the second direction D2 in the gate structure GS. The first and second transistors TR2 may be arranged in the second direction D2.

A plurality of metal lines ML may be electrically connected to the active region ACT through an active contact ACNT and electrically connected to the gate structures GS through a gate contact GCNT. The first and second transistors TR2 may be connected to each other through the metal lines ML, or connected to other elements to form a semiconductor circuit.

In the first and second transistors TR1 and TR2, the width of the gate structure GS between the active regions ACT, for example, the length of the gate structure GS in the second direction D2, tends to decrease, e.g., from generation to generation. In the trend of decreasing width of the gate structure GS, if three metal lines ML respectively connected to the source, drain, and gate structure GS are disposed in parallel in the second direction D2, the distance between the metal lines ML may become too close, and/or each of the metal lines ML may become too thin, either or both of which may deteriorate the performance of the semiconductor device.

Referring to FIG. 1, the gate structure GS may include a line portion GL extending in the first direction D1 and an extension portion GE contacting an end of the line portion GL. An active region ACT may intersect the line portion GL in the second direction D2. The extension portion GE may be spaced apart from the active regions ACT in the first direction D1.

The active region ACT may include source/drain regions adjacent to the line portion GL in the second direction D2. Each of the source/drain regions may be connected to metal lines ML through active contacts ACNT. Alternatively or additionally, in the gate structure GS, instead of the metal line ML being connected to the line portion GL intersecting the active region ACT, the metal line ML may be connected to the extension portion GE through the gate contact GCNT. The length of the channel region of the transistor may be reduced, and the metal lines ML connected to the gate, source, and drain of the transistor may be spaced apart from each other by a predetermined distance or more.

To prevent or reduce the likelihood of fand/or impact from plasma damage, a structure capable of discharging plasma ions accumulated in the gate structure GS through the substrate is desirable. For example, by electrically connecting the metal line ML connected to the gate structure GS to the active region of the substrate, the plasma ions accumulated in the gate structure GS may be discharging, for example, to the substrate.

As the size of the transistor is decreasing, e.g., with generation, it is difficult to directly connect the metal line ML connected to the gate structure GS to the active region ACT. Therefore, according to the comparative example of FIG. 1, the first and second antenna devices AD1 and AD2 may be formed in a region separate from the region where the first and second transistors TR1 and TR2 are formed. For example, the first and second antenna devices AD1 and AD2 may be formed in a first region A1 and a second region A2, respectively. The first and second antenna devices AD1 and AD2 may be regions doped with impurities, such as the active region.

The first transistor TR1 may be connected to the first antenna device AD1 through a metal line ML connected to the gate structure GS, and the second transistor TR2 may be connected to the second antenna device AD2 through a metal line ML connected to the gate structure GS. Each of the first and second antenna devices AD1 and AD2 may be connected to the metal line ML through an active contact ACNT.

To protect or help to protect the gate structures GS from plasma damage, the first and second antenna devices AD1 and AD2 should be formed in a separate area from the area where the first and second transistors TR1 and TR2 are formed, and the first and second transistors TR1 and TR2 should be connected to the first and second antenna devices AD1 and AD2 through metal lines ML, so the area required for or used for the semiconductor device increases, and the degree of freedom of the metal line ML may decrease.

Alternatively or additionally, if the gate structures GS of the first and second transistors TR1 and TR2 are electrically separated and/or isolated and/or insulated from each other, the metal lines ML connected to the gate structures GS should be connected to the antenna devices in a state of being electrically separated from each other, so the degree of freedom of the metal line ML may be further reduced, and it may be difficult to reduce the area required for the semiconductor device.

According to some example embodiments, instead of including a separate antenna device connected to the gate structure GS through the metal line ML, the semiconductor device may include a dummy active region adjacent to the lower surface of the extension portion GE. In detail, the dummy active region may be formed so that the dummy active region intersect the extension portions GE of the gate structures GS of the first and second transistors TR1 and TR2 that are electrically separated from each other. Plasma ions accumulated in the gate structures GS may be released through the dummy active region.

According to some example embodiments, since the semiconductor device does not have to include a separate antenna device, the area required for or used for the semiconductor device may be reduced. This area reduction may improve the yield and/or the reliability of the semiconductor device. Alternatively or additionally, since the semiconductor device does not require or use a metal line for connecting the extension portion GE of the gate structure GS and the dummy active region, a degree of freedom of the metal line may be improved.

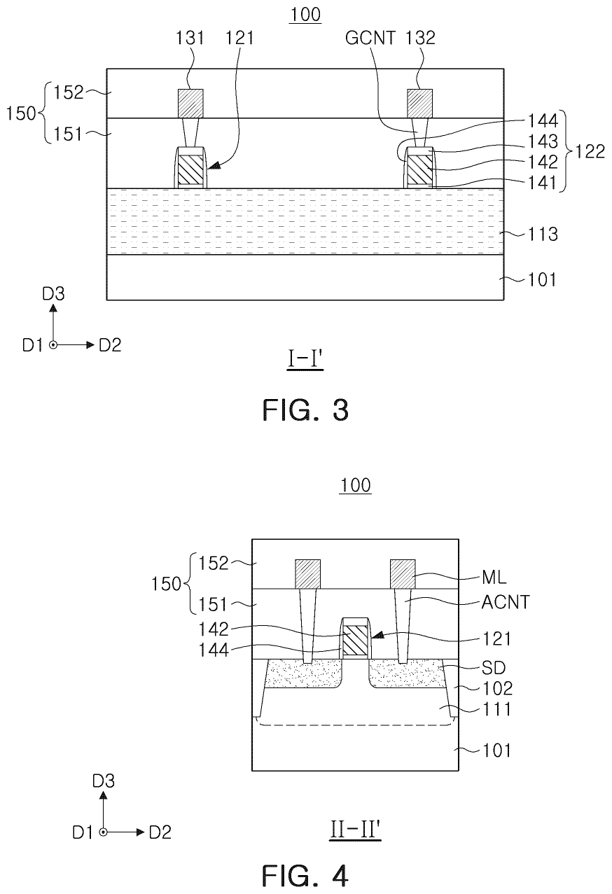

FIG. 2 is a layout diagram of a semiconductor device according to some example embodiments.

Referring to FIG. 2, a semiconductor device 100 according to some example embodiments may include a first transistor TR1 and a second transistor TR2.

The first transistor TR1 may include a first gate structure 121 and a first active region 111. The first gate structure 121 may include a first line portion GL1 extending in a first direction D1 and an extension portion GE1 contacting the first line portion GL1 at one end of the first line portion GL1.

The first active region 111 may intersect the first line portion GL1 in a second direction D2. The first active region 111 may include, e.g., may be doped with an impurity of the first conductivity type. For example, the first active region 111 may include an n-type impurity. The first active region 111 may include source/drain regions on both sides adjacent to the first line portion GL1 in the second direction D2. The source/drain regions may be doped with an impurity of a higher concentration, e.g., a much higher concentration than, than the remaining region of the first active region 111.

The second transistor TR2 may have a structure similar to the first transistor TR1.

The second transistor TR2 may include a second gate structure 122 and a second active region 112. The second gate structure 122 may include a second line portion GL2 extending in the first direction D1 and an extension portion GE2 contacting the second line portion GL2 at one end of the second line portion GL2. The second active region 112 may intersect the second line portion GL2 in the second direction D2.

The source/drain regions of the first and second transistors TR1 and TR2 may be connected to the metal lines ML through the active contacts ACNT, and the extension portions GE1 and GE2 may be connected to the metal lines ML through the gate contacts GCNT. The first and second transistors TR1 and TR2 may be electrically connected to each other through the metal lines ML, or may be electrically connected to other elements. FIG. 2 illustrates a first metal line 131 connected to the first extension portion GE1 through the gate contact GCNT among the metal lines ML, and a second metal line 132 connected to the second extension portion GE2 through the gate contact GCNT among the metal lines ML. In some example embodiments, the first metal line 131 may be electrically isolated from the second metal line 132.

The width of the first and second line portions GL1, GL2 in the second direction D2 has a narrowing trend., e.g., from generation to generation. Accordingly, the first metal lines 131 cannot disposed adjacent to all of the two metal lines connected to the first active region 111 in the second direction D2. Similarly, the second metal lines 132 cannot disposed adjacent to all of the two metal lines connected to the second active region 112 in the second direction D2. In some example embodiments, one metal line ML among the metal lines ML electrically connected to the source/drain regions SD of the first active region 111 may be spaced apart from the first metal line 131 in the second direction D2, and another metal line ML among the metal lines ML electrically connected to the source/drain regions SD of the first active region 111 may be offset from the first metal line 131 in the second direction D2.

In example embodiments illustrated in FIG. 2, the gate structures 121 and 122 of the first and second transistors TR1 and TR2 may be electrically separated or isolated. The fact that the gate structures 121 and 122 are electrically separated may refer to the fact that the gate structures 121 and 122 are connected to different electrical networks. For example, different and in some cases independent signals may be applied to the first and second metal lines 131 and 132, and as a result, different and in some cases independent signals may be applied to the gate structures 121 and 122.

The second transistor TR2 may be disposed in a second direction D2 with the first transistor TR1. Referring to FIG. 2, the first extension portion GE1 and the second extension portion GE2 may be disposed side by side in the second direction D2.

According to some example embodiments, the semiconductor device 100 may further include a dummy active region 113 intersecting the first extension portion GE1 and the second extension portion GE2 in the second direction D2. The lower surfaces of the first extension portion GE1 and the second extension portion GE2 and the upper surface of the dummy active region 113 may be in contact with each other. In some example embodiments, the dummy active region 113 may be separated from the first active region 111 and the second active region 112.

In some example embodiments, the dummy active region 113 may include, e.g. may be doped with an impurity of the first conductivity type such as but not limited to phosphorus and/or arsenic. In some example embodiments, the dummy active region 113 may also be doped with impurities of a second conductivity type, but at a much lower concentration than a concentration of impurities of the first concentration type; example embodiments are not limited thereto. The dummy active region 113 may provide channel regions at a position in contact with the lower surfaces of the first gate structure 121 and the second gate structure 122. During a semiconductor process, plasma ions accumulated in the first gate structure 121 through the first metal line 131 and/or plasma ions accumulated in the second gate structure 122 through the second metal line 132 may be emitted to the substrate through the channel regions. For example, the dummy active region 113 may reduce the antenna ratio associated with the first and second gate structures 121 and 122.

In some example embodiments, the substrate may be grounded, e.g., may be electrostatically grounded, during a plasma operation such as one or more of an etching operation or a deposition operation. Because the substrate is grounded, plasma ions may be discharged from the dummy active region 113 to the ground.

According to some example embodiments, the dummy active region 113 is disposed in a form that crosses the first extension portion GE1 and the second extension portion GE2 in the second direction D2, thereby protecting both gate structures GS1 and GS2 that are electrically separated from each other from plasma damage.

Alternatively or additionally, since the area where the dummy active region 113 is disposed overlaps (or partially overlaps) the area where the first and second extension portions GE1 and GE2 provided to connect the gate structures GS1 and GS2 of the transistors TR1 and TR2 to the metal lines 131 and 132 are disposed, an additional area of the semiconductor device may not be required. Therefore, the area efficiency of the semiconductor device may be improved.

Alternatively or additionally, since the dummy active region 113 is in direct contact with the first and second extension portions GE1 and GE2, an additional metal line may not be required to dispose the first and second extension portions GE1 and GE2 on the dummy active region 113. Therefore, the degree of freedom of other metal lines ML may be improved.

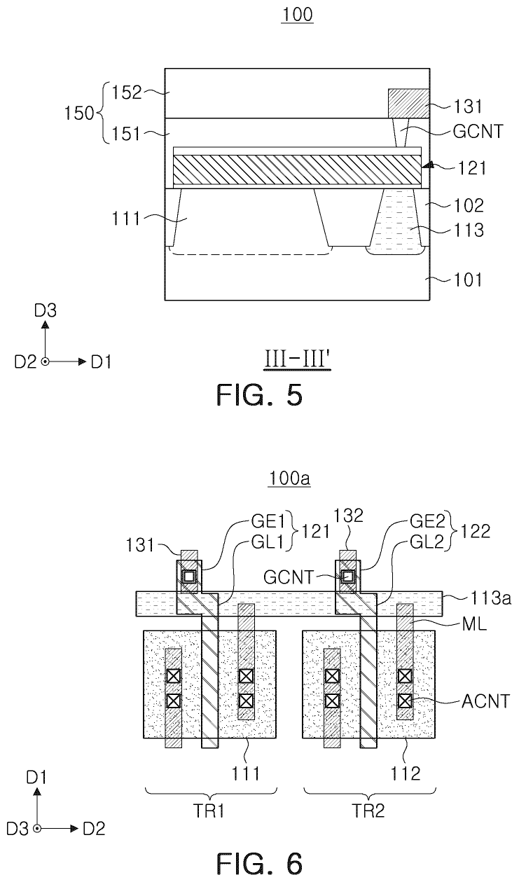

Hereinafter, with reference to FIGS. 3 to 5, the structure of the semiconductor device 100 described with reference to FIG. 2 is described in more detail.

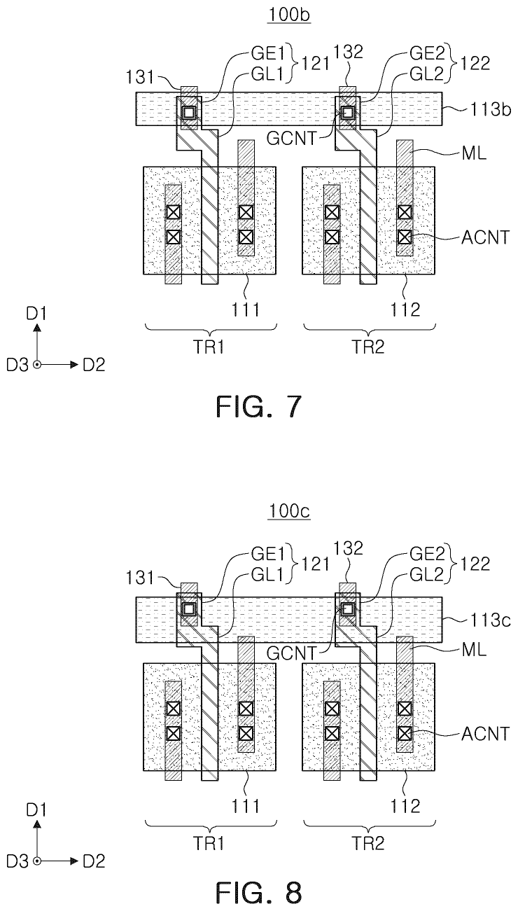

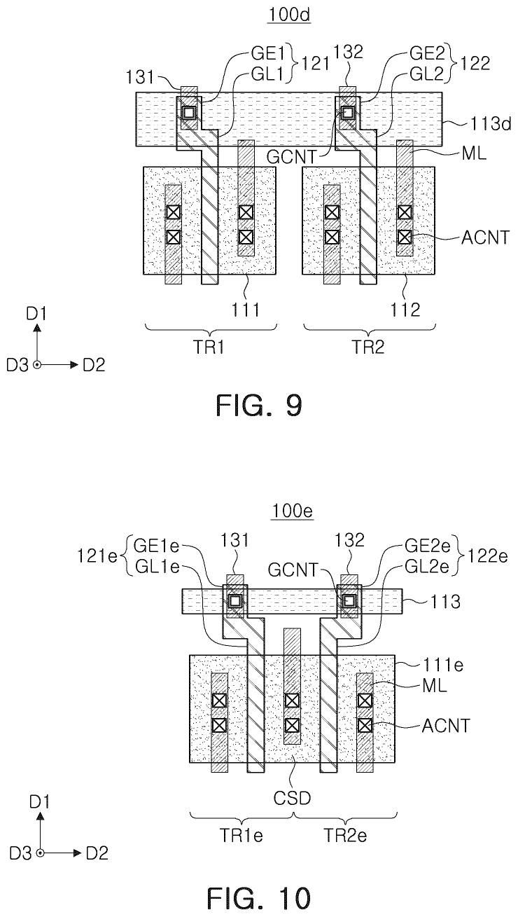

FIG. 3 is a cross-sectional view taken along line I-I′ of FIG. 2, FIG. 4 is a cross-sectional view taken along line II-II′ of FIG. 2, and FIG. 5 is a cross-sectional view taken along line III-III′ of FIG. 2.

Referring to FIGS. 3 to 5, the semiconductor device 100 may include a substrate 101, a device isolation film 102, active regions 111, 112 and 113, first and second gate structures 121 and 122, a gate contact GCNT, an active contact ACNT, metal lines 131 and 132, and an insulating layer 150. The insulating layer 150 may include insulating layers 151 and 152. The insulating layer 151 may surround the first and second gate structures 121 and 122, and the gate contact GCNT. The insulating layer 152 may surround the metal lines 131 and 132.

The substrate 101 may include a semiconductor material, such as but not limited to one or more of a group IV semiconductor, a group III-V compound semiconductor, or a group II-VI compound semiconductor. For example, the group IV semiconductor may include silicon, germanium, or silicon-germanium. The substrate 101 may also be provided as one or more of a bulk wafer, an epitaxial layer, a silicon on insulator (SOI) layer, or a semiconductor on insulator (SeOI) layer. The substrate 101 may include doped regions such as an N well region NWELL. A first direction D1 and a second direction D2 parallel to the upper surface of the substrate 101 are defined, and a third direction D3 perpendicular to the upper surface of the substrate 101 is defined.

The device isolation film 102 may define active regions 111, 112 and 113 in the substrate 101. For example, the device isolation film 102 may be formed by a shallow trench isolation (STI) process. As illustrated in FIG. 4, the device isolation film 102 may include a region extending deeper into the lower portion of the substrate 101 between adjacent active regions 111, 112 and 113, but is not limited thereto. The device isolation film 102 may be made of an insulating material, for example, an oxide, a nitride, or a combination thereof.

Referring to FIG. 3, the dummy active region 113 according to some example embodiments may extend in the same second direction D2 as the direction in which the gate structures 121 and 122 are arranged. The dummy active region 113 may be doped with an impurity of the same first conductivity type as the first and second active regions 111 and 112 described with reference to FIG. 2. For example, the first conductivity type impurity may be an n-type impurity and in some example embodiments may include one or more of arsenic or phosphorus, at the same or at different concentrations, at the same or at different depths.

The upper surface of the dummy active region 113 may contact the lower surface of the gate structures 121 and 122, in detail, the extension portions GE1 and GE2 described with reference to FIG. 2. For example, the dummy active region 113 may intersect the extension portions GE1 and GE2 based on a plane parallel to the upper surface of the substrate 101.

Referring to FIG. 3, the dummy active region 113 may be in contact with the first extension portion GE1 of the first gate structure 121 and the second extension portion GE2 of the second gate structure 122. In example embodiments illustrated in FIG. 3, the dummy active region 113 may overlap with or be overlapped by the first metal line 131 and the gate contact GCNT connecting the first extension portion GE1 and the first metal line 131 in the third direction D3. At the same time, the dummy active region 113 may overlap with or be overlapped by the second extension portion GE2 of the second gate structure, the second metal line 132, and the gate contact GCNT connecting the second extension portion GE2 and the second metal line 132 in the third direction D3. However, example embodiments are not limited thereto, and the dummy active region 113 does not necessarily have to overlap with or be overlapped by the first metal line 131, the second metal line 132, and the gate contacts GCNT.

In some example embodiments, the gate structures 121 and 122 may have the same structure. For example, the second gate structure 122 may include a gate insulating layer 141, a gate electrode layer 142, a gate capping layer 143, and gate spacer layers 144.

The gate insulating layer 141, the gate electrode layer 142, and the gate capping layer 143 may be sequentially laminated from or deposited on the upper surface of the substrate 101. The gate insulating layer 141 may include one or more of an oxide, a nitride, or a high-k material. The high-k material may mean a dielectric material having a higher dielectric constant than a silicon oxide film SiO₂. In some example embodiments, the gate insulating layer 141 may be composed of multiple layers, and/or may be disposed to extend onto the side surface of the gate electrode layer 142.

The gate electrode layer 142 may include a conductive material, for example, a metal nitride such as one or more of a titanium nitride (TiN), a tantalum nitride (TaN), or a tungsten nitride (WN), and/or a metal material such as one or more of aluminum (Al), tungsten (W), or molybdenum (Mo), and/or a semiconductor material such as doped polysilicon. The gate electrode layer 145 may be composed of two or more multilayers.

The gate capping layer 143 may be disposed on the upper portion of the gate electrode layer 142, and the lower surface and the side surfaces may be surrounded by the gate electrode layer 142 and the gate spacer layers 144, respectively. The gate capping layer 143 may be formed of, for example, one or more of oxide, nitride, and oxynitride.

The gate spacer layers 144 may be disposed on both side surfaces of the gate electrode layer 142. In some example embodiments, the gate spacer layers 144 may be formed of a multilayer structure. The gate spacer layers 144 may be formed of one or more of oxide, nitride, and oxynitride, and in detail, may be formed of a low-k film. For example, the gate spacer layers 144 may include at least one of SiO, SiN, SiCN, SiOC, SiON, and SiOCN.

According to some example embodiments, the dummy active region 133 may provide a path for emitting plasma ions transmitted to the gate structures 121 and 122 through the metal lines 131 and 132 during a semiconductor process to the substrate 101. The semiconductor process may include one or more of an etching process or a deposition process; example embodiments are not limited thereto. The path may be formed by a chucking operation, such as a chucking operation of the substrate 101; example embodiments are not limited thereto.

According to some example embodiments, a dummy active region 113 disposed to be in contact with each of the electrically separated gate structures 121 and 122 may effectively protect the electrically separated gate structures 121 and 122 from plasma damage, while not adversely affecting or only slightly adversely affecting the normal operation of the semiconductor device 100.

However, example embodiments are not limited to the case where the dummy active region 113 is doped with an n-type impurity. For example, the dummy active region 113 may include an impurity of the same conductivity type and/or the same concentration as the substrate 101. For example, the dummy active region 113 may include a p-type impurity, and may not additionally be doped with an impurity.

FIG. 4 illustrates a cross-section of a first transistor TR1 region cut in the second direction D2. The second transistor TR2 described with reference to FIG. 2 may also have the same structure as the first transistor TR1.

Referring to FIG. 4, the first active region 111 may be disposed to intersect the first gate structure 121 in the second direction D2. In detail, the first active region 111 may intersect the line portion GL1 described with reference to FIG. 2 in the second direction D2.

Referring to FIG. 4, the first active region 111 may include source/drain regions SD. The source/drain regions SD may be disposed adjacent to the first line portion GL1 of the first gate structure 121 in the second direction D2. Referring to FIG. 4, the gate spacer layers 144 may insulate the source/drain regions SD and the gate electrode layer 142.

The source/drain regions SD may provide a source and a drain of the first transistor TR1 as described with reference to FIG. 2. The source/drain regions SD may be formed of an epitaxial layer; however, example embodiments are not limited thereto. The source/drain regions SD may include, for example, one or more of silicon (Si), silicon germanium (SiGe), or silicon carbide (SiC). In addition, the source/drain regions SD may further include impurities such as arsenic (As) and/or phosphorus (P). In some example embodiments, the source/drain regions SD may include a plurality of regions including different concentrations of elements and/or doping elements, such as but not limited to halo regions and/or lightly-doped drain regions.

In some example embodiments, the source/drain regions SD may have a higher concentration of impurities than the first active region 111. For example, the first active region 111 may include impurities diffused from the source/drain regions SD in an area in contact with the source/drain regions SD.

The source/drain regions SD may be electrically connected to the metal lines ML via active contacts ACNT.

The impurity concentrations of the source/drain regions SD and the dummy active region 113 may be the same, but may be different. For example, the impurity concentration of the dummy active region 113 may be lower than, e.g., an order of magnitude or more lower than, the impurity concentration of the source/drain regions SD.

Referring to FIG. 5, the lower surface of the first gate structure 121 may be in contact with the first active region 111 and the dummy active region 113. The first active region 111 may provide the source and drain of the first gate structure 121, and the dummy active region 113 may reduce the antenna ratio by increasing the area in which the gate insulating layer of the first gate structure 121 contacts the active region.

According to some example embodiments, the dummy active region 113 may overlap or be overlapped by the first extension portion GE1 provided to connect the first metal line 131 to the first gate structure 121 and the second extension portion GE2 provided to connect the second metal line 132 to the second gate structure 122 in the third direction D3. Therefore, the semiconductor device 100 may have the dummy active region 113 within the area where the first and second transistors TR1 and TR2 are provided, and the antenna ratio may be reduced. Accordingly, the gate structures 121 and 122 may be protected or at least partly protected from plasma damage while suppressing the increase in the area of the semiconductor device 100.

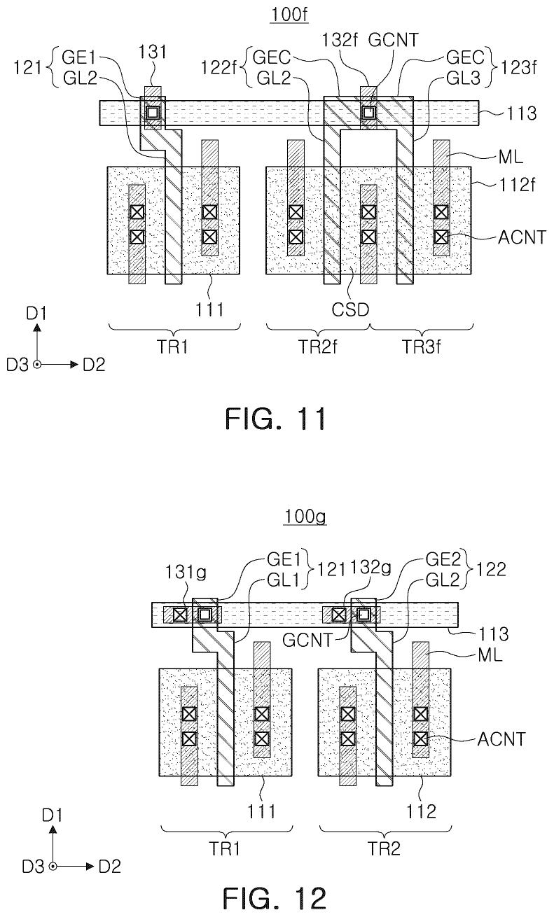

One or more of the position, size, and shape of the dummy active region 113 according to some example embodiments are not limited to those described with reference to FIGS. 2 to 5. The dummy active region 113 may intersect all or part of each of the extension portions of the transistors arranged in the direction in which the dummy active region 113 is extended. Hereinafter, the structure of the semiconductor device according to some example embodiments will be described with reference to FIGS. 6 to 9.

FIGS. 6 to 9 are layout diagrams of semiconductor devices according to some example embodiments.

Semiconductor devices 100a, 100b, 100c and 100d of FIGS. 6 to 9 may have structures similar to the semiconductor device 100 described with reference to FIGS. 2 to 5. Hereinafter, the structures of the semiconductor devices 100a, 100b, 100c and 100d will be described with a focus on differences from the semiconductor device 100.

According to some example embodiments, the dummy active region 113 does not necessarily have to overlap the metal lines 131 and 132 and the gate contacts GCNT.

In the semiconductor device 100 of FIG. 2, the dummy active region 113 may overlap or be overlapped by the first metal line 131, the second metal line 132, and the gate contacts GCNT for connecting the first metal line 131 to the first extension portion GE1 and connecting the second metal line 132 to the second extension portion GE2 in the third direction D3.

On the other hand, in the semiconductor device 100a of FIG. 6, the dummy active region 113a may be disposed and may be misaligned with the gate contacts GCNT in the third direction D3. For example, the dummy active region 113a may be disposed between the gate contacts GCNT and the active regions 111 and 112 with respect to the upper surface of the substrate.

According to some example embodiments, the width of the dummy active region in the first direction D1 may be determined according to the antenna ratio required for or used for the gate structures 121 and 122.

In the semiconductor device 100 of FIG. 2, the dummy active region 113 and the first extension portion GE1, and the dummy active region 113 and the second extension portion GE2 may intersect each other. One end of the first extension portion GE1 and one end of the second extension portion GE2 may not overlap with the dummy active region 113 in the third direction D3 and may contact the device isolation film.

On the other hand, the dummy active region 113b of the semiconductor device 100b of FIG. 7 may overlap with or be overlapped by one end of the first extension portion GE1 and one end of the second extension portion GE2 in the third direction D3. In some example embodiments, the dummy active region 113b of the semiconductor device 100b may at least partly overlap with at least one end of the first extension portion GE1 and at least one end of the second extension portion GE2 in the third direction D3. Compared with the dummy active region 113 of FIG. 2, the dummy active region 113b of FIG. 7 may increase the area of the channel region formed on the lower surface of the gate structures 121 and 122 and further reduce the antenna ratio.

In the semiconductor device 100 of FIG. 2, the dummy active region 113 may not overlap the first line portion GL1 and the second line portion GL2 at all.

On the other hand, the dummy active region 113c of the semiconductor device 100c of FIG. 8 may overlap or be overlapped by a portion of the first line portion GL1 and the second line portion GL2 in the third direction D3. In some example embodiments, the dummy active region 113c of the semiconductor device 100c may at least partly overlap with at least one end of the first line portion GL1 and at least one end of the second line portion GL2 in the third direction D3. Compared with the dummy active region 113 of FIG. 2, the dummy active region 113c of FIG. 8 may increase the area of the channel region formed on the lower surface of the gate structures 121 and 122 and further reduce the antenna ratio.

The semiconductor device 100d of FIG. 9 may have a dummy active region 113d that overlaps or is overlapped by one end of the first extension portion GE1 and one end of the second extension portion GE2, and also overlaps a part of the first line portion GL1 and the second line portion GL2. The dummy active region 113d of FIG. 9 may provide a further reduced antenna ratio compared to the dummy active regions 113c and 113d of FIGS. 7 and 8.

Meanwhile, the size and/or the shape of the gate structures of the semiconductor device, and the size and shape of the dummy active region crossing the gate structures are not limited to those described with reference to FIGS. 2 to 9. For example, in the examples of FIGS. 2 to 9, the extension portion of the gate structure has a quadrangular shape and is adjacent to the end of the line portion in the second direction D2. However, the extension portion may have various shapes such as a polygon, a circle, or the like and may be adjacent to the end of the line portion in the first direction D1.

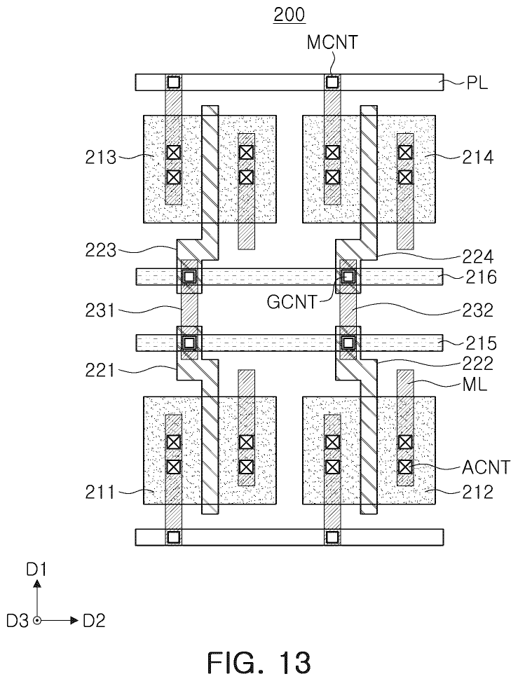

The structure of the semiconductor device 100 according to some example embodiments is not limited to that described with reference to FIGS. 2 to 9. For example, at least some of the transistors whose extension portion intersects the dummy active region 113 may share the active region, and some of the transistors may have gate structures GS electrically connected thereto. Hereinafter, the structure of the semiconductor device according to some example embodiments will be described with reference to FIGS. 10 and 11.

FIGS. 10 and 11 are layout diagrams of a semiconductor device according to some example embodiments.

Referring to FIG. 10, a semiconductor device 100e according to some example embodiments may have a structure similar to the semiconductor device 100 described with reference to FIGS. 2 to 5. Hereinafter, the structure of the semiconductor device 100e will be described with a focus on differences from the semiconductor device 100.

The semiconductor device 100e may include an active region 111e and may include a first gate structure 121e and a second gate structure 122e. The active region 111e may intersect the first and second gate structures 121e and 122e in a second direction D2.

The active region 111e, the first and second gate structures 121e and 122e may form a first transistor TR1e and a second transistor TR2e. The active region 111e may include a common source/drain region CSD between the first and second gate structures 121 and 122. The common source/drain region may be provided as a common source/drain of the first and second transistors TR1e and TR2e.

The active region 111e may be connected to metal lines ML through active contacts ACNT, and the gate structures 121e and 122e may be connected to metal lines ML through gate contacts GCNT. FIG. 10 illustrates a first metal line 131 connected to a first extension portion GE1a of a first gate structure 121 through a gate contact GCNT among metal lines ML, and a second metal line 132 connected to a second extension portion GE2a of a second gate structure 122 through a gate contact GCNT.

According to some example embodiments, the semiconductor device 100e may further include a dummy active region 113 intersecting the first extension portion GE1e and the second extension portion GE2e in a second direction D2.

Unlike the semiconductor device 100 of FIG. 2, in the semiconductor device 100e of FIG. 10, a first transistor TR1e and a second transistor TR2e may share a common source/drain region CSD. Therefore, the distance between the first and second extension portions GE1e and GE2e of the semiconductor device 100a may be closer than the distance between the first and second extension portions GE1 and GE2 of the semiconductor device 100.

Meanwhile, design rules, which are rules for designing the layout of the semiconductor device, may be defined. For example, a design rule may be defined so that the active regions separated from each other have a distance, such as a dynamically determined, or alternatively, a predetermined distance or more. According to some example embodiments, even when the distance between the first and second extension portions GE1e and GE2e is close, the design rule may be followed and the antenna ratio of both the first and second gate structures 121e and 122e may be improved by arranging one dummy active region 113 crossing the first and second extension portions GE1a and GE2a.

Referring to FIG. 11, a semiconductor device 100f according to some example embodiments may have a structure similar to that of the semiconductor device 100 described with reference to FIGS. 2 to 5. Hereinafter, the structure of the semiconductor device 100f will be described with a focus on differences from the semiconductor device 100.

The semiconductor device 100f may include a first active region 111, a second active region 112f, a first gate structure 121, a second gate structure 122f, and a third gate structure 123f. The first active region 111 and the first gate structure 121 may constitute a first transistor TR1. The second active region 112f, the second gate structure 122f, and the third gate structure 123f may constitute second and third transistors TR2f and TR3f.

The second gate structure 122f and the third gate structure 123f may be electrically connected. In the example of FIG. 11, the second and third gate structures 122f and 123f may include a common extension portion GEC. The second gate structure 122f may be composed of a second line portion GL2 and a common extension portion GEC, and the third gate structure 123f may be composed of a third line portion GL3 and a common extension portion GEC. The second active region 112f may include a common source/drain region CSD between the second and third line portions GL2 and GL3. The second and third transistors TR2f and TR3f may share a common source/drain region CSD.

The first to third transistors TR1, TR2f and TR3f may be connected to metal lines ML via active contacts ACNT and gate contacts GCNT. FIG. 7 illustrates a first metal line 131 connected to a first extension portion GE1 of a first gate structure 121, and a second metal line 132f connected to a common extension portion GEC of the second and third gate structures 122f and 123f.

According to some example embodiments, the semiconductor device 100f may further include a dummy active region 113 intersecting the first extension portion GE1 and the common extension portion GEC in the second direction D2. For example, the dummy active region 113 may be disposed to cross the gate structures that are electrically separated from each other, thereby improving the antenna ratio of each of the gate structures, but the gate structures that share the dummy active region 113 do not have to be electrically separated from each other. Therefore, the dummy active region 113 according to some example embodiments does not limit the freedom of electrical connection between the transistors.

Alternatively or additionally, referring to FIGS. 2 to 11, the dummy active region may be disposed to contact the lower surface of the extension portions of the gate structures that are electrically separated from each other, thereby reducing the antenna ratio of the gate structures. However, the present inventive concept does not exclude a case in which the gate structures are additionally connected to the active region using a metal line.

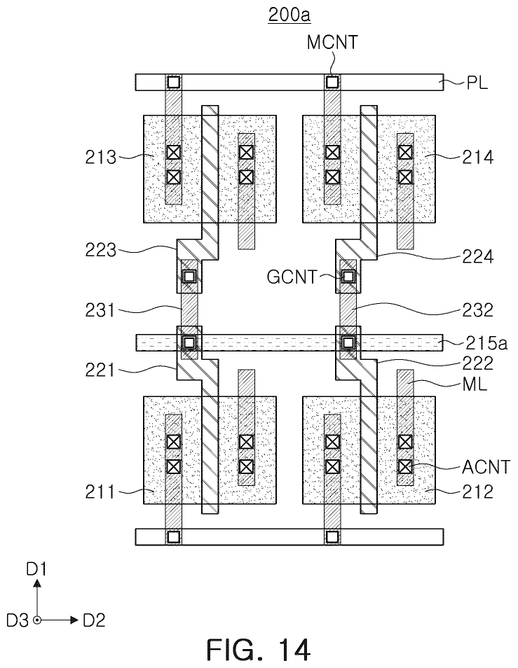

Hereinafter, the structure of a semiconductor device according to some example embodiments will be described with reference to FIG. 12.

FIG. 12 is a layout diagram of a semiconductor device according to some example embodiments.

A semiconductor device 100g of FIG. 12 may have a structure similar to the semiconductor device 100 described with reference to FIGS. 2 to 5. Hereinafter, the structure of the semiconductor device 100g will be described with a focus on differences from the semiconductor device 100.

Referring to FIG. 12, a dummy active region 113 may be disposed to intersect the first extension portion GE1 and the second extension portion GE2 in the second direction D2. The upper surface of the dummy active region 113 may be in contact with the lower surface of the first extension portion GE1 and the lower surface of the second extension portion GE2.

The first metal line 131g connected to the first extension portion GE1 through the gate contact GCNT and the second metal line 132g connected to the second extension portion GE2 through the gate contact GCNT may each include a portion extending in the second direction D2.

According to some example embodiments, the first metal line 131g may not only be connected to the first extension portion GE1, but may also be further connected to a dummy active region 113 through the active contact ACNT. The dummy active region 113 may provide a channel region in a region in contact with the first extension portion GE1, and may further provide an antenna diode in a region connected to the first metal line 131g. In detail, since the dummy active region 113 may form a p-n junction with the substrate, an antenna diode connected in the reverse direction between the first metal line 131g and the substrate may be provided.

Likewise, the second metal line 132g may be connected not only to the second extension portion GE2, but also to the dummy active region 113 via an active contact ACNT. The dummy active region 113 may further provide an antenna diode that is connected in the reverse direction between the second metal line 132g and the substrate.

During a semiconductor process, when a voltage greater than the breakdown voltage is applied to the gate structures 121 and 122 due to plasma ions collected on the gate structures 121 and 122, the antenna diode may be turned on which may more effectively discharge the plasma ions to the substrate. On the other hand, during normal operation of the semiconductor device 100g, a voltage greater than the breakdown voltage may not be applied to the gate structures 121 and 122, and the antenna diode may be maintained in a turned-off state.

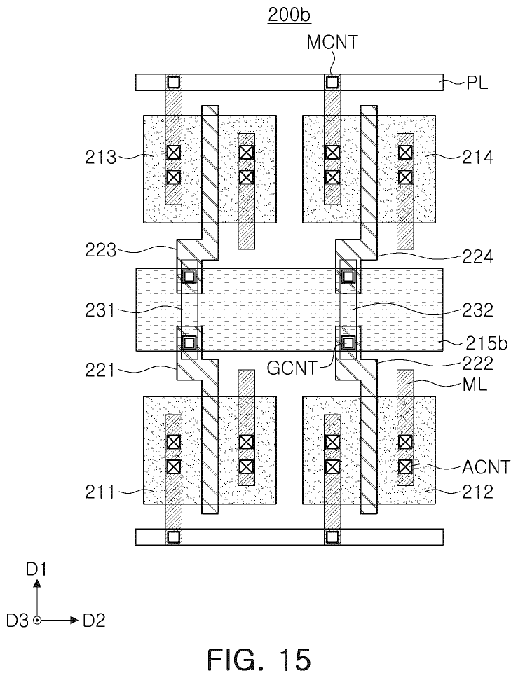

Referring to FIGS. 2 to 12, example embodiments have been described, taking as an example a case in which transistors are arranged in a second direction D2. In some example embodiments, a semiconductor device may include a plurality of transistors arranged in a first direction D1 and a second direction D2 on an upper surface of a substrate. Hereinafter, a structure of a semiconductor device according to embodiments will be described with reference to FIGS. 13 to 15.

FIGS. 13 to 15 are layout diagrams of a semiconductor device according to embodiments.

Referring to FIG. 13, a semiconductor device 200 may include transistors disposed on a semiconductor substrate along a first direction D1 and a second direction D2. The semiconductor device 200 may include a plurality of gate structures 221 to 224 disposed along a first direction D1 and a second direction D2 and extending in the first direction D1, and a plurality of active regions 211 to 214 respectively intersecting the plurality of gate structures 221 to 224 in the second direction D2. In some example embodiments, the plurality of active regions 211 and 212 may each intersect at least one of the plurality of gate structures 221 and 222, and the plurality of active regions 213 and 214 may each intersect at least one of the plurality of gate structures 223 and 224.

At least some of the plurality of active regions 211 to 214 may be doped with impurities of different conductivity types. For example, the first and second active regions 211 and 212 may be doped with n-type impurities, and the third and fourth active regions 213, 214 may be doped with p-type impurities.

The plurality of active regions 211 to 214 may include source/drain regions in regions adjacent to the plurality of gate structures 221 to 224 in the second direction D2, respectively. A single gate structure and an active region intersecting the gate structure may constitute a transistor.

A plurality of transistors may be electrically connected via metal lines ML. The active regions 211 to 214 may be connected to the metal lines ML via active contacts ACNT, and the gate structures 221 to 224 may be connected to the metal lines ML via gate contacts GCNT. The metal lines ML may be disposed at a first height determined from the upper surface of the semiconductor substrate and may extend in a first direction D1. The metal lines ML may be connected to the gate structures 221 to 224 and the active regions 211 to 214.

The power lines PL may supply voltage to the semiconductor device 200 and may be electrically connected to the source/drain regions formed in the active regions 211 to 214 through the metal contacts MCNT. In the example of FIG. 12, two power lines PL extending in the second direction D2 are illustrated. One of the power lines PL may supply a first voltage, and the other may supply a second voltage having a lower potential than the first voltage. For example, the first voltage may be a power voltage, and the second voltage may be a ground voltage. In some example embodiments, the power lines PL may be disposed at a second height higher than the first height from the upper surface of the semiconductor substrate.

Similar to the semiconductor device 100 described with reference to FIG. 2, the gate structures 221 to 224 may each include a line portion and an extension portion. The line portion may intersect with the active region constituting the transistor, and the extension portion may contact a gate contact GCNT for connecting the gate structure to the metal line ML.

In the example of FIG. 13, between the gate structures arranged in the second direction D2, the extension portions may also be arranged in the second direction D2. Between the gate structures arranged in the first direction D1, the extension portions may be disposed to face each other. FIG. 12 illustrates a first metal line 231 electrically connecting the extension portions of the first and third gate structures 221 and 223 among the metal lines ML, and a second metal line 232 electrically connecting the extension portions of the second and fourth gate structures 222, 224. In some example embodiments, the first metal line 231 and the second metal line 232 may be electrically separated.

According to some example embodiments, a semiconductor device 200 may include a first dummy active region 215 that contacts the lower surface of each of the extension portions of the first and second gate structures 221 and 222 and extends to intersect the extension portions in a second direction D2, and a second dummy active region 216 that contacts the lower surface of each of the extension portions of the third and fourth gate structures 223 and 224 and extends to intersect the extension portions in a second direction D2.

In some example embodiments, the first and second dummy active regions 215 and 216 may include, e.g., may be doped with n-type impurities. For example, the first and second dummy active regions 215 and 216 may be doped with impurities of the same conductivity type as the first and second active regions 211 and 212, and may be doped with impurities of a different conductivity type than the third and fourth active regions 213, 214. In some example embodiments, the first and second dummy active regions 215 and 216 may include impurities having a lower concentration than the source/drain regions included in the first and second active regions 211 and 212.

According to some example embodiments, the first dummy active region 215 may protect or help protect gate structures 221 and 222 that are electrically separated from each other from plasma damage, and the second dummy active region 216 may protect or help protect gate structures 223 and 224 that are electrically separated from each other from plasma damage.

Alternatively or additionally, since the first and second dummy active regions 215 and 216 may overlap with extension portions for connecting metal lines ML to the gate structures 221 to 224 in the third direction D3, an increase in the area of the semiconductor device 200 may be suppressed. However, the first and second active regions 215 and 216 do not necessarily have to overlap with the gate contacts GCNT and metal lines 231 and 232 disposed on the upper portions of the extension portions in the third direction D3.

Referring to FIG. 14, a semiconductor device 200a according to some example embodiments may have a structure similar to the semiconductor device 200 described with reference to FIG. 12. Hereinafter, the structure of the semiconductor device 200a will be described with a focus on differences from the semiconductor device 200.

According to some example embodiments, the semiconductor device 200a may include a dummy active region 215a that contacts the lower surface of each of the extension portions of the first and second gate structures 221 and 222 and extends to intersect the extension portions in the second direction D2. However, unlike the semiconductor device 200 described with reference to FIG. 12, the dummy active region intersecting the extension portions of the third and fourth gate structures 223 and 224 is not included, and a device isolation film may be disposed on the lower surface of the extension portions.

In the example of FIG. 14, since the first and third gate structures 221 and 223 are electrically connected through the first metal line 231, the antenna ratio may be determined based on the sum of the channel areas of the first and third gate structures 221 and 223 and the area of the first metal line 231. Depending on the connection structure of the transistors, if the gate structures may satisfy the target antenna ratio in the case where the semiconductor device includes only one of the first and second dummy active regions described with reference to FIG. 12, the semiconductor device may include only one of the first and second dummy active regions.

Referring to FIG. 15, a semiconductor device 200b according to some example embodiments may have a structure similar to the semiconductor device 200 described with reference to FIG. 13. Hereinafter, the structure of the semiconductor device 200b will be described with a focus on differences from the semiconductor device 200.

According to some example embodiments, the semiconductor device 200 may include a dummy active region 215b extending in the first direction D1 and the second direction D2 to contact the lower surface of all of the extension portions of the first to fourth gate structures 221 to 224.

According to some example embodiments described with reference to FIGS. 2 to 15, the semiconductor device may include a dummy active region intersecting the extension portions for connecting the gate structure to the metal line. The dummy active region may reduce the antenna ratio and alleviate or improve upon plasma damage by increasing the area of the channel region connected to the gate structures without substantially increasing the area required for the semiconductor device.

Alternatively or additionally, since the dummy active region may be shared between gate structures that are electrically separated from each other, the dummy active region may not restrict the circuit design. By forming the dummy active region across a plurality of extension portions on the lower surfaces of the plurality of extension portions arranged in one direction, the gate structures may be effectively protected from plasma damage regardless of the electrical connection structure between the gate structures.

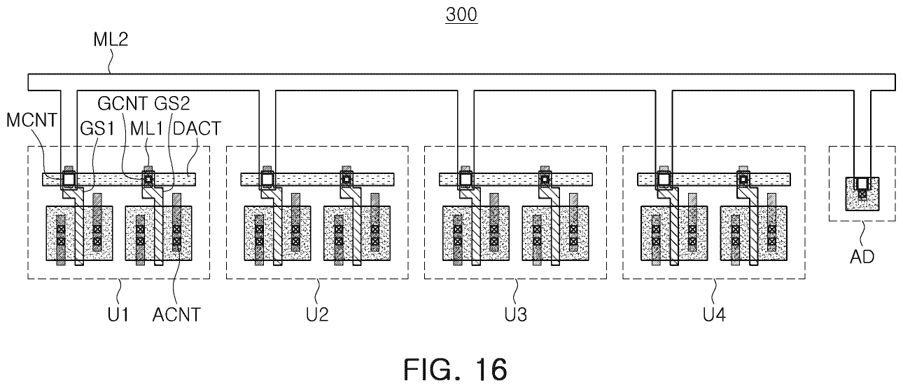

FIG. 16 is a layout diagram of a semiconductor device according to some example embodiments.

Referring to FIG. 16, a semiconductor device 300 may include a plurality of unit circuits U1 to U4, a metal line ML2 electrically connected to the unit circuits U1 to U4, and an antenna circuit AD electrically connected to the metal line ML2.

The unit circuits U1 to U4 may be circuits having the same connection structure, or may be circuits having different connection structures. According to some example embodiments, the unit circuits U1 to U4 may include transistors arranged in at least one direction, regardless of the connection structure. The transistors may be connected to the metal lines ML1 through an active contact ACNT and a gate contact GCNT. Each of the unit circuits U1 to U4 may include a dummy active region DACT disposed to intersect the extension portions of the gate structures GS1 and GS2 arranged in one direction, in the direction in which the extension portions are arranged. The respective dummy active regions may be shared by gate structures that are electrically separated from each other.

Among the gate structures of the unit circuits U1 to U4, the gate structures to which the same signal should be applied may be electrically connected from the outside of the unit circuits U1 to U4. For example, among the first metal lines ML1 connected to the gate structures through the gate contact GCNT, the gate structures to which the same signal should be applied may be connected to the second metal line ML2 through the metal contact MCNT. The second metal line ML2 may be disposed at a higher position on the substrate of the semiconductor device 300 than the first metal lines ML1, but the present inventive concept is not limited thereto.

The sum of the areas of the metal lines and the sum of the areas of the channel regions for determining the antenna ratio may be added based on an electrically connected network. For example, when determining the antenna ratio by assuming that a semiconductor process is performed while the second metal line ML2 is formed, the sum of the areas of the metal lines may be determined as the sum of the areas of the second metal line ML2 and the areas of the first metal lines ML1 connected to the second metal line ML2. Alternatively or additionally, the sum of the areas of the channel regions may be determined as the sum of the areas of the channel regions of all gate structures connected to the second metal line ML2 through the first metal lines ML1.

If antenna devices requiring additional circuit area are to be disposed in the respective unit circuits U1 to U4, the circuit area occupied by the antenna devices in the respective unit circuits U1 to U4 and the plasma damage protection performance of the antenna devices may have to be compromised. If a sufficient number of antenna devices are not formed in the respective unit circuits U1 to U4 to reduce the circuit area of the unit circuits U1 to U4, a number of additional antenna devices may have to be connected to the second metal line ML2 outside the unit circuits U1 to U4 to satisfy the target antenna ratio at the second metal line (ML2) stage.

On the other hand, according to some example embodiments, dummy active regions for increasing the antenna ratio may be disposed on the semiconductor substrate without increasing the circuit area of each of the unit circuits U1 to U4, regardless of the connection structure of the gate structures. Therefore, the plasma damage protection performance of the dummy active region does not need to be compromised with the circuit area, and dummy active regions having sufficient plasma damage protection performance may be disposed in the respective unit circuits U1 to U4. Accordingly, the number of antenna devices AD that are to be reinforced to satisfy the target antenna ratio in the upper metal line stage including the second metal line ML2 may be reduced. As a result, the area used for the semiconductor device 300 may be reduced. This may in some cases improve one or more of costs, yield, or reliability; example embodiments are not limited thereto.

As set forth above, a semiconductor device according to some example embodiments includes a dummy active region below an extension portion for connecting a metal line to a gate of a transistor, and may discharge plasma ions accumulated in the gate through the dummy active region. Since the dummy active region does not require or use an additional circuit area and an additional metal line, the circuit area may be reduced and the degree of freedom of the metal line may be improved.

A semiconductor device according to some example embodiments may include a dummy active region intersecting the extension portions of a plurality of gates connected to metal lines electrically separated from each other. The dummy active region may effectively protect the plurality of respective gates electrically separated from each other from plasma damage.

While some example embodiments have been illustrated and described above, it will be apparent to those of ordinary skill in the art that modifications and variations could be made without departing from the scope of example embodiments as defined by the appended claims. Additionally, example embodiments are not necessarily mutually exclusive with one another. For example, some example embodiments may include one or more features described with reference to one or more figures, and may also include one or more other features described with reference to one or more other figures. Example embodiments are not limited thereto.

What is claimed is:

1. A semiconductor device comprising:
a first gate structure including a first line portion extending in a first direction parallel to an upper surface of a substrate, and a first extension portion contacting an end of the first line portion;
a second gate structure including a second line portion extending in the first direction and spaced apart from the first line portion in a second direction, and a second extension portion contacting an end of the second line portion and spaced apart from the first extension portion in the second direction, the second direction parallel to the upper surface of the substrate and intersecting the first direction;
a first active region intersecting the first line portion in the second direction;
a second active region intersecting the second line portion in the second direction;
a dummy active region contacting a lower surface of the first extension portion and a lower surface of the second extension portion, extending in the second direction, and separated from the first active region and the second active region; and
a plurality of metal lines including a first metal line electrically connected to the first extension portion and a second metal line electrically connected to the second extension portion and electrically isolated from the first metal line.

2. The semiconductor device of claim 1, further comprising:
a first gate contact connecting the first extension portion and the first metal line; and
a second gate contact connecting the second extension portion and the second metal line.

3. The semiconductor device of claim 1, wherein
the first metal line is further connected to the dummy active region through a first active contact, and
the second metal line is further connected to the dummy active region through a second active contact.

4. The semiconductor device of claim 1, wherein the dummy active region is at least partly overlapped by at least one end of the first extension portion and at least one end of the second extension portion in a third direction perpendicular to the upper surface of the substrate.

5. The semiconductor device of claim 1, wherein the dummy active region is at least partly overlapped by at least one end of the first line portion and at least one end of the second line portion in a third direction perpendicular to the upper surface of the substrate.

6. The semiconductor device of claim 1, wherein
the first active region includes first source/drain regions adjacent to the first line portion, and
the second active region includes second source/drain regions adjacent to the second line portion.

7. The semiconductor device of claim 6, wherein the dummy active region includes an impurity at a lower concentration than the first source/drain regions and the second source/drain regions.

8. The semiconductor device of claim 1, wherein the dummy active region includes an n-type impurity.

9. The semiconductor device of claim 1, wherein the dummy active region includes a p-type impurity having a same concentration as the substrate.

10. The semiconductor device of claim 1, wherein the first active region, the second active region, and the dummy active region are defined by an element isolation film on the upper surface of the substrate.

11. The semiconductor device of claim 1, wherein
the first extension portion is adjacent to the end of the first line portion in the second direction, and
the second extension portion is adjacent to the end of the second line portion in the second direction.

12. The semiconductor device of claim 1, wherein
the plurality of metal lines further include third metal lines electrically connected to source/drain regions of the first active region through active contacts, and
the first metal line is spaced apart from one metal line of the third metal lines in the second direction and offset from another metal line among the third metal lines in the second direction.

13. A semiconductor device comprising:
a plurality of gate structures respectively extending in a first direction parallel to an upper surface of a substrate, and arranged in a second direction parallel to the upper surface of the substrate and intersecting the first direction, at least some of the plurality of gate structures electrically isolated from each other;
a plurality of active regions respectively intersecting at least one of the plurality of gate structures in the second direction, and arranged in the second direction; and
a dummy active region separated from the plurality of active regions and extending in the second direction to contact respective lower surfaces of the plurality of gate structures.

14. The semiconductor device of claim 13, wherein
the plurality of gate structures include a first gate structure and a second gate structure adjacent to each other,
the plurality of active regions include a first active region intersecting the first gate structure and the second gate structure, and
the first active region includes a shared source/drain region between the first gate structure and the second gate structure.

15. The semiconductor device of claim 13, wherein the plurality of gate structures include a plurality of third gate structures electrically connected to each other.

16. The semiconductor device of claim 15, wherein the plurality of third gate structures each include a line portion extending in the first direction and share an extension portion contacting an end of the line portion.

17. A semiconductor device comprising:
a plurality of first gate structures each including a first line portion extending in a first direction parallel to an upper surface of a substrate, and a first extension portion contacting an end of the first line portion, and arranged in a second direction intersecting the first direction;
a plurality of first active regions each intersecting at least one of the plurality of first gate structures and arranged in the second direction;
a plurality of second gate structures each including a second line portion extending in the first direction and a second extension portion contacting an end of the second line portion, arranged in the second direction, and spaced apart from the plurality of first gate structures in the first direction;
a plurality of second active regions each intersecting at least one of the plurality of second gate structures, and arranged in the second direction; and
a dummy active region extending in the first direction and the second direction to contact lower surfaces of the respective first extension portions of the plurality of first gate structures and lower surfaces of the respective second extension portions of the plurality of second gate structures,
wherein at least some of the respective first extension portions of the plurality of first gate structures are electrically isolated from each other, and the respective second extension portions of the plurality of second gate structures are electrically isolated from each other.

18. The semiconductor device of claim 17, wherein the plurality of first active regions include an n-type impurity,
the plurality of second active regions include a p-type impurity, and
the dummy active region includes an n-type impurity.

19. The semiconductor device of claim 17, wherein
the plurality of first active regions include source/drain regions adjacent to the plurality of first gate structures, and
the dummy active region includes an impurity having a lower concentration than the source/drain regions.

20. The semiconductor device of claim 17, further comprising:
power lines extending in the second direction and connected to at least one of the plurality of first active regions and the plurality of second active regions.
